(19) United States
(12) Patent Application Publication
(10) Pub. No.: US 2014/0102504 A1
(43) Pub. Date: Apr. 17, 2014

(54) Full Surface Contact Twin Solar Cell

(71) Applicant: Kehinde Orekoya, Cedar Park, TX (US)

(72) Inventor: Kehinde Orekoya, Cedar Park, TX (US)

(21) Appl. No.: 14/053,595

(22) Filed: Oct. 14, 2013

Related U.S. Application Data
(60) Provisional application No. 61/795,245, filed on Oct. 15, 2012.

(51) Int. Cl. H01L 31/068

(52) U.S. Cl. CPC H01L 31/0684
USPC 136/244

(57) ABSTRACT

The full surface contact twin solar cell is in fact two cells in one; this means the cell can generate a greater output than that of a single cell of comparable dimension and construction at certain times during the solar insolation daily cycle. This can greatly improve the efficiency per unit area perpendicular to the insolation source. This is possible due to the cells employment of full surface area collection at both the top and bottom plates. This twin cell configuration utilizes boron phosphorus (BoP) as a barrier between the top (front) and bottom (rear) junctions to allow for dual collection and distribution. Moreover, each cell can be connected to each adjacent cell in either a series or parallel manner. This flexibility extends the range of configurations that can be realized to the limit defined by the overall number of cells.

### CROSS-REFERENCE TO RELATED APPLICATIONS

This application is a continuation of U.S. patent application No. 61/795,245 filed Oct. 15, 2012.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

The present invention is in the technical field of energy generation. More particularly, the present invention is in the technical field of renewable energy generation by solar cells.

Due to the low efficiency level of solar cells for energy generation, continued research is undertaken to improve the collection percentage and conversion rate and minimize heat loss for photovoltaic systems. Contemporary solar systems employ a single level of interconnected panels (typically series connected) to achieve the desired output, while at the individual cell level, multilayered single cells with uni-directional current flow have been implemented to improve efficiency.

### SUMMARY OF THE INVENTION

The present invention is a full service contact twin solar cell that allows for dual insolation (top and bottom), vertical and horizontal mounting and varied inter-panel configurations.

### BRIEF DESCRIPTION OF THE DRAWING

FIG. 1 is a perspective view of the top plate of the present invention.

FIG. 2 is a perspective view of the top n-material layer of the present invention.

FIG. 3 is a perspective view of the top base of the present invention.

FIG. 4 is a perspective view of the p-material substrate of the present invention.

FIG. 5 is a perspective view of the bottom base of the present invention.

FIG. 6 is a perspective view of the bottom n-material layer of the present invention.

FIG. 7 is a perspective view of the bottom plate of the present invention.

### DETAILED DESCRIPTION OF THE INVENTION

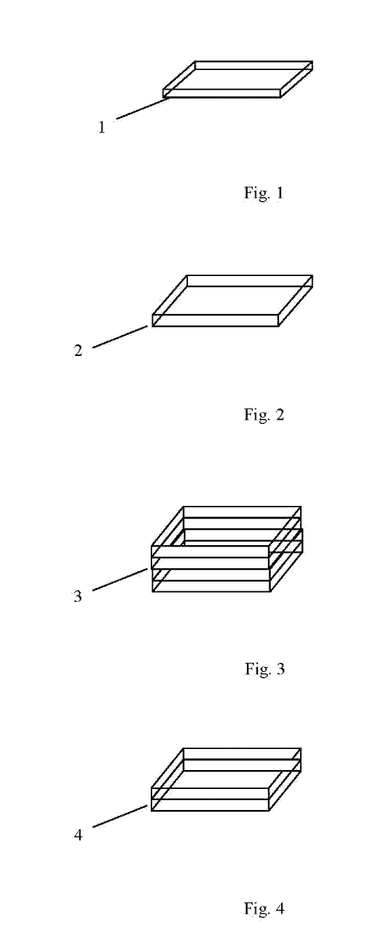

Referring now to the invention in more detail, in FIGS. 1 and 7, the top and bottom plates, 1 and 7, are shown, respectively. These plates are the collection surfaces for the invention. Each surface allows for sunlight refraction over the entire area, which maximizes the insolation of the invention.

The construction details of the invention as shown in FIGS. 1 and 7 are that the plates, 1 and 7, are made of glass with dimensions of 150 mm (height)×150 mm (width)×(variable thickness). Although, a thickness of 95.55 nm is recommended, additional embodiments may employ thicknesses or lesser or greater extent dependent upon the environment in which the system is deployed, the refraction index of the particular glass material or other factors that will affect the ratio of refraction to incidence light energy.

Referring now to FIGS. 2 and 6, there is shown the top and bottom n-material layers, 2 and 6, respectively. These layers initiate the flow of current from the top down and the bottom up through the cells.

The construction details of the invention as shown in FIGS. 2 and 6 are that the n-material layers, 2 and 6, are made of silicon (Si) doped with phosphorus (P) with dimensions of 150 mm (height)×150 mm (width)×(variable thickness). Although, a thickness of 1.5 μm is recommended, additional embodiments may employ thicknesses or lesser or greater extent such that the incident energy is transferred through the layers such that excess radiation effect is not present at the cell surfaces, which would tend to negatively impact the efficiency.

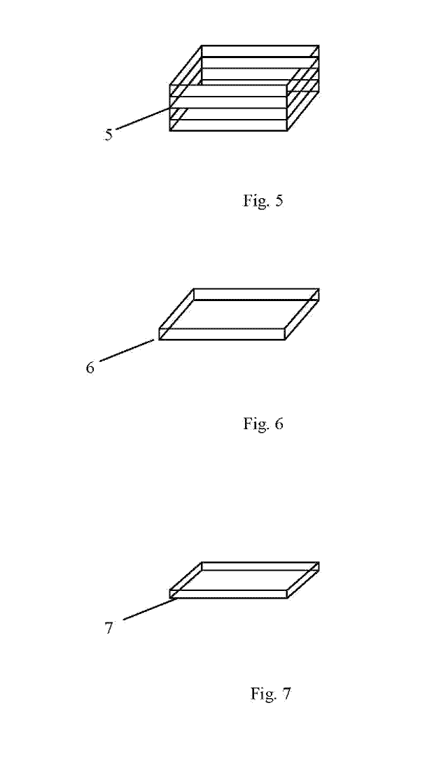

Referring now to FIGS. 3 and 5, there is shown the top and bottom bases, 3 and 5, respectively. These layers accept the influx energy from the photons incident in 2 and 6, respectively.

The construction details of the invention as shown in FIGS. 3 and 5 are that the bases, 3 and 5, are made of silicon (Si) with dimensions of 150 mm (height)×150 mm (width)×(variable thickness).

Although, a thickness of 98.4 μm is recommended, additional embodiments may employ thicknesses or lesser or greater extent such that the electron flow (electrical energy from the incident photons) is at a rate such that the potential established between the layer and its adjacent outer layer is maximized.

Referring now to FIG. 4, there is shown the p-material substrate, 4. This layer isolates the top and bottom cells from each other.

The construction details of the invention as shown in FIG. 4 is that the p-material substrate, 4, is made of silicon (Si) doped with boron (Bo) with dimensions of 150 mm (height)×150 mm (width)×(variable thickness). This thickness may range up to 3.0 mm or any lesser or greater extent that provides sufficient isolation of the top cell from the bottom cell.

In further detail, the top plate, 1, top n-material layer, 2, top base, 3, and p-material layer, 4, constitute a complete solar cell. Incident photons pass through 1 into 2. The excess energy created is passed to 3 where a charge imbalance is created. This imbalance is the energy that is available for current flow out of the top cell.

Similarly, the bottom plate, 7, bottom n-material layer, 6, bottom base, 5, and p-material layer, 4, constitute a complete solar cell. Incident photons pass through 7 into 6. The excess energy created is passed to 5 where a charge imbalance is created. This imbalance is the energy that is available for current flow out of the top cell.

The p-material substrate is doped with Bo to serve as a barrier between the top and bottom cells. The bases, 3 and 5, are sufficiently large to be able to absorb the excess energy created by the incident photons. This minimizes the amount of recombination in 4 and increases the amount of current available to flow to adjacent cells.

As the top and bottom cells are isolated, they may be individually connected to external cells. This provides a level of flexibility in solar array panel configuration that is not currently available.

To promote overall insolation into the twin solar cell, the invention may be mounted vertically or at any advantageous angle that will allow insolation on both the top and bottom surfaces. One such embodiment orients the twin solar cell in a vertical direction (normal to the mounting surface) and employs reflectors on either side of the cell. These reflectors are tilted with respect to the vertical axis of the cell at equidistances forming a concave insolation area to maximize the amount of incident sunlight on the cells top and bottom surfaces. This configuration also provides a more consistent solar energy generation profile as compared to the standard flat or horizontal mounting architecture, which tends to follow a Gaussian profile. For increased insolation, the reflectors may be Fresnel.

The present invention may be constructed using commercially known substrate growth, doping and fabrication procedures.

The twin solar cell is not a multilayer solar cell for uni-directional energy flow. It may and is in fact intended to be connected in arrays consisting of similar cells. The isolation between the top and bottom cells allows for connecting a single twin solar cell into two separate (electrically and physically) circuits. This flexibility enables a wide range of electrical circuit configurations as opposed to simple parallel or series arrays as is presently used in solar system construction schemes.

The advantages of the present invention include dual simultaneous insolation, full surface contact, variable mount, dual external connectivity, and increased efficiency over single cells of comparable dimensionality. The flexibility of the external connections enables the construction of multiple solar array panel configurations.

In broad embodiment, the present invention is a full surface contact twin solar cell that enhances insolation, improves efficiency and provides multiple panel array configuration possibilities.

While the foregoing written description of the invention enables one with skill in solar cell fabrication to make and use the full surface contact twin solar cell in what is considered presently to be the best mode thereof, those with skill in solar cell array construction and solar system design will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

1. The present invention is a full contact twin collection surface solar cell able to perform dual simultaneous insolation.

2. The present invention allows for dual connectivity to external electrical circuitry.

3. The present invention provides increased efficiency over single sided solar cells of comparable dimensionality due to increased mounting flexibility over single-sided solar cells.
